(19) United States
(12) Patent Application Publication
(10) Pub. No.: US 2005/0068798 A1
(43) Pub. Date: Mar. 31, 2005

(54) Committed access rate (CAR) system architecture

(75) Inventors: Chien-Hsin Lee, Cupertino, CA (US); Rahul Saxena, Sunnyvale, CA (US); Kinyip Sit, Sunnyvale, CA (US)

Correspondence Address: Jung-Hua Kuo Attorney at Law;c/o PortfolioIP, P.O. Box 52050, Minneapolis, MN, 55402, US

(73) Assignee: Intel Corporation, Santa Clara, CA (US)

(21) Appl. No.: 10/675,009

(22) Filed: Sep. 30, 2003

(51) Int. Cl. G11C 15/00; G11C 8/00

(52) U.S. Cl. 365/49; 365/230.03

(57) ABSTRACT

Systems and methods for committed access rate (CAR) system architecture in an IP/Ethernet network with optional dynamic packet memory reservation are disclosed. The method includes classifying each received packet into a quality of service (QoS) group using the packet header information, defining a traffic transmission rate profile such as by using a token bucket model to measure and check the traffic rate profile of the incoming packet against a corresponding service level agreement (SLA), marking the packet as in profile or out of profile, and performing packet buffer memory reservation to guarantee memory space for in profile CAR packets. Buffer memory reservation may be via static or dynamic memory reservation. Dynamic memory reservation eliminates the need for hard boundaries to restrict non-CAR packets. A push-out (e.g., head-drop) mechanism may be employed to push out non-CAR packets when the network traffic is congested.

### BACKGROUND

Committed Access Rate (CAR) or Committed Information Rate (CIR) is the data rate that an access provider guarantees will be available on a connection. CAR is a way to provide Quality of Service (QoS) in an IP/Ethernet network. By providing CAR to a targeted QoS group in the IP/Ethernet network, a preserved and guaranteed bandwidth specified in a predetermined service level agreement (SLA) can be provided to that targeted QoS group rather than merely providing a best effort service. The ability to provide QoS in the IP/Ethernet network is important for supporting real time applications and for deploying a pure IP network in areas where most of the existing infrastructure may be based on ATM or SONET.

Currently, CAR is generally only available in large and expensive networking systems. Thus, CAR is not cost effective and thus is generally not available in an enterprise network. However, to support the QoS in the IP/Ethernet network, it may be preferable to deploy CAR in the IP/Ethernet network from end to end and not merely within the core of the network.

In addition, the increased demand to support real-time or interactive audio and video applications in an enterprise IP/Ethernet network is a key driving force for providing QoS in an enterprise network. Currently, supervision is used to prevent network congestion. However, supervision does not solve potential congestion problems in an enterprise network when dealing with multicast (Mcast) traffic. For example, in a N−1 (i.e., N ports sending traffic to 1 port) situation, Mcasts can cause a large burst in packet flow in a very short period of the time. The large burst makes it difficult to mix audio, video and data traffic together without limiting the quality of the audio/video traffic or separating the real-time traffic from data traffic.

One way of addressing the issue of large bursts is through the use of packet memory reservations. In packet memory resource reservation, a set amount of memory is allocated in an attempt to guarantee bandwidth for a particular type of network traffic.

For example, 50% of the available bandwidth in a network switch may be preserved for a targeted QoS group and the remaining 50% may be reserved for other types of network traffic. With packet memory reservation, when one type of traffic reaches the capacity of its allocated memory, packets from that traffic are dropped. However, the other type of traffic may still have available memory but because that memory is preserved, the available memory cannot be utilized. Under utilization of packet memory space leads to the bandwidth for the system to be underutilized which also makes the system inefficient.

Furthermore, if the traffic reaching capacity is Mcast traffic, it would be undesirable to drop Mcast packets because such dropping may limit the quality of real-time audio/video traffic.

### BRIEF DESCRIPTION OF THE DRAWINGS

FIG. 1 is a block diagram illustrating a network router implementing committed access rate (CAR) architecture.

FIG. 2 is a block diagram illustrating a control pipe of the network router of FIG. 1 in more detail.

FIG. 3 is a block diagram illustrating the general structure of a transmit queue of the network router of FIG. 1 in more detail.

FIG. 4 is a block diagram illustrating a packet buffer memory of the network router of FIG. 1 in more detail.

FIG. 5 summarizes memory allocations and management for CAR packets, non-CAR multicast packets and non-CAR Ucast packets.

FIG. 6 is a flowchart illustrating a process performed by the network switch implementing CAR architecture.

FIG. 7 is a flowchart illustrating packet buffer memory reservation process of FIG. 6 in more detail.

### DESCRIPTION OF SPECIFIC EMBODIMENTS

Systems and methods for committed access rate (CAR) system architecture in an IP/Ethernet network with optional dynamic packet memory reservation are disclosed. It should be appreciated that the present invention can be implemented in numerous ways, including as a process, an apparatus, a system, a device, a method, or a computer readable medium such as a computer readable storage medium or a computer network wherein program instructions are sent over optical or electronic communication lines. Several inventive embodiments of the present invention are described below to enable any person skilled in the art to make and use the invention. Descriptions of specific embodiments and applications are provided only as examples and various modifications will be readily apparent to those skilled in the art. The general principles defined herein may be applied to other embodiments and applications without departing from the spirit and scope of the invention. Thus, the present invention is to be accorded the widest scope encompassing numerous alternatives, modifications and equivalents consistent with the principles and features disclosed herein. For purpose of clarity, details relating to technical material that is known in the technical fields related to the invention have not been described in detail so as not to unnecessarily obscure the present invention.

The method generally includes classifying each received packet into a quality of service (QoS) group using the packet header information, defining a traffic transmission rate profile using, for example, a token bucket model to measure and check the traffic rate profile of the incoming packet against a corresponding service level agreement (SLA), marking the packet as in profile or out of profile packet, and performing packet buffer memory reservation to guarantee storage for in profile CAR packets.

The packet classification may be performed via a content addressable memory (CAM), or via a multi-bank ternary CAM (T-CAM). The token bucket model can be realized in hardware and facilitates in controlling CAR packets as well as input rate limiting (IRL) packets and output rate limiting (ORL) packets. A CAR packet is in profile if it is within the corresponding SLA such that the in profile CAR packet receives congestion-free service. A CAR packet is out of profile if the SLA is exceeded and is provided with best effort service and/or dropped. IRL and ORL in profile packets receive best effort service whereas IRL and ORL out of profile packets are dropped.

Buffer memory reservation may be via static memory reservation in which memory space is statically partitioned between CAR packets and non-CAR packets. Alternatively, the buffer memory reservation may be via dynamic memory reservation in which packet buffer memory is dynamically allocated between CAR packets and non-CAR packets and a push-out mechanism (e.g., head-drop) is employed to push out non-CAR packets when the network traffic is congested. Examples of push out mechanisms include head drop which refers to dropping the oldest packets and tail drop which refers to dropping the newest packets. Separate multicast queues and thresholds can optionally be defined for multicast packets and a multicast counter can be provided to facilitate tracking of multicast packets.

A network device, e.g., a router or a switch, for providing committed access rate (CAR) in an IP/Ethernet network generally includes a control pipe configured to classify each received packet into a quality of service (QoS) group using packet header information. The control pipe is further configured to define a traffic transmission profile using a token bucket model to define the traffic behavior for a given traffic flow and measuring against a corresponding SLA, to mark the packet as in profile or out of profile, and to perform packet buffer memory reservation to guarantee storage space for in profile CAR packets. The network device also includes a transmit queue in communication with the control pipe and a packet buffer memory in communication with the transmit queue. The transmit queue includes transmit queue entries and transmit queue entry memory. The packet buffer memory is configured to receive and store received packets. The control pipe is configured to perform packet buffer memory reservation to guarantee transmit queue and packet buffer memory space for in profile CAR packets.

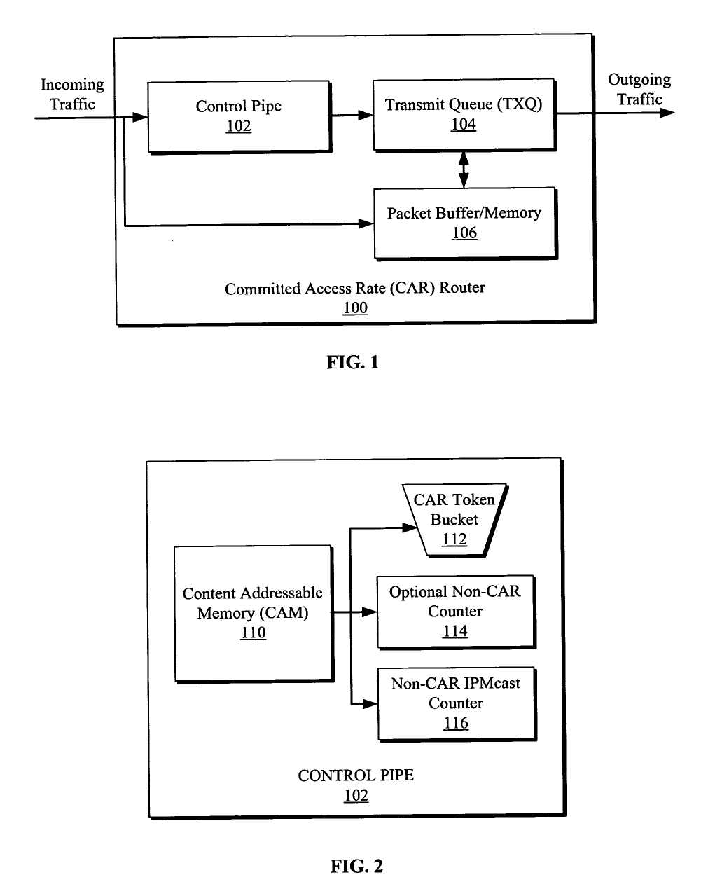

FIG. 1 is block diagram illustrating a network device 100 implementing committed access rate (CAR) architecture. Network device generally refers to a network router, a network switch, a network device that have both routing and switching functions, or the like. Routing generally refers to the forwarding of packets primarily based on layer 3 header information while switching generally refers to the forwarding of packets primarily based on layer 2 header information. As noted, CAR is the data rate that an access provider guarantees will be available on a connection. CAR is a way to provide Quality of Service (QoS) in an IP/Ethernet network. By providing CAR to a targeted QoS group in the IP/Ethernet network, a preserved and guaranteed bandwidth specified in a predetermined service level agreement (SLA) can be provided to that targeted QoS group rather than merely providing a best effort service. The ability to provide QoS in the IP/Ethernet network is important for supporting real time or interactive audio and video applications and for deploying a pure IP network in areas where most of the existing infrastructure may be based on ATM or SONET. It is noted that although a network device is used to illustrate the concepts presented herein, similar components and mechanisms can also be embodied in a network switch. For example, CAR may be integrated and implemented in a single chip network device system, making CAR available to more users and making deployment of CAR ubiquitous.

CAR classifies traffic into different QoS groups based on SLA and gives each QoS group a predetermined service in terms of bandwidth and resource allocation. In other words, it makes conformed CAR traffics immune from congestion due to other traffics in the network. The CAR network device 100 is able to mix various types of network traffic (e.g., CAR, IRL, ORL, etc.) with low cost and high quality.

As shown in FIG. 1, the network CAR network device 100 generally includes a control pipe 102, a transmit queue (TxQ) 104 and packet buffer/memory 106 for storing packets arriving on the incoming traffic. The control pipe 102 receives the packet headers for processing. The transmit queue 104 places the packets to be transmitted on the outgoing queues. Packets in the queues are transmitted out of the transmit port in FIFO (first-in first-out) order.

FIG. 2 is a block diagram illustrating the control pipe 102 of the network device of FIG. 1 in more detail. As shown, the control pipe 102 includes content addressable memory (CAM) 110, a CAR token bucket 112, an optional non-CAR counter 114, and a multicast (Mcast) counter 116. The CAR token bucket 112 models the SLA so as to measure and check the traffic rate profile of the incoming CAR packet against the SLA. The control pipe 102 performs various packet processing functions for implementing CAR in the network device 100 including packet classification, traffic profile definition, policing and marking, and resource reservation. Each of these functions will be described in more detail below.

When a packet arrives at the network device 100, the control pipe 102 utilizes information in the packet header for processing. In particular, the control pipe 102 performs a packet classification function to classify incoming packet traffic into different QoS groups using the information available in the packet header. For example, the packet header may contain any combination of data such as L2 source address, L2 destination address, IP source address, IP destination address, VLAN Tag, TCP socket numbers, and/or various other packet header information. The level of packet classification capabilities depends on where the CAR network device 100 is deployed within the network and the type of the application.

Packet classification is configured in hardware and is determined in the control pipe 102 of the network device 100 via the CAM 110. The CAM 110 is optionally a multi-bank Ternary CAM (T-CAM) as the T-CAM permits partial-match retrieval and is useful for packet classification. However, any other suitable addressable memory may be used. The multi-bank TCAM may provide classification for L2/L3/MPLS packets separately. Packet matches with programmed fields with content in the TCAM are marked and assigned a unique pointer for further packet rule lookups and packet processing.

After packet classification and identification, the control pipe 102 performs traffic rate profile check. In one embodiment, a token bucket model is used to measure and check the traffic rate profile of the incoming packet against the SLA. The configurable parameters used in the token bucket model include token refill rate r, token size s and burst size b. Thus, the long-term average rate is r*s and the burst size b maps to the maximum storage requirement in the network device 100. The token bucket model assumes that the outgoing bandwidth is at least equal to or greater than the average rate r*s, which can be controlled by Weighted Fair Queuing (WFQ) in the output stage. WFQ is a technique for selecting packets from multiple queues. WFQ avoids the problem of starvation that can arise when strict priorities are used. Otherwise, the storage requirement would be unbounded. The same token bucket model may be used to define CAR, ORL (output or outbound rate limiting) and/or IRL (input or inbound rate limiting) traffic. A counter to track the usage per flow and a memory element to store the available space may be used to realize the token bucket model in hardware. A pointer assigned in the packet classification stage is used to reference the current usage in the memory.

It is noted that although the token model may be utilized, any other suitable mechanism to measure incoming traffic rate against configured traffic rate profile (resource over time) may be employed. In addition, any suitable modifications to the token model as described may be employed. For example, two cascading token buckets may be employed in which the first token bucket measures incoming CAR traffic rate against configured traffic rate profile and marks the packet as in profile or out of profile. The out of profile bucket may then be passed to a second, preferably larger token bucket that measures the out of profile packet against a more relaxed traffic rate profile configuration. The second token bucket determines whether the out of profile packet receives best of effort service or simply dropped.

Once the traffic rate profile of the incoming packet has been checked and measured against the SLA using, e.g., the token bucket model, the packet can be categorized as an in profile or an out of profile packet. CAR packets within the confirmed SLA, i.e., if token is available, are in profile packets and are treated as committed packets and enjoy congestion-free service. CAR packets exceeding the SLA are out of profile packets and may be dropped and/or treated as best effort packets. IRL and ORL in profile packets receive best effort service while IRL and ORL out of profile packets are dropped. Services for the two classes of packets for CAR, ORL and IRL traffic are summarized in TABLE 1 below.

TABLE 1

| Traffic Type | In Profile Packets | Out of Profile Packets |
|---|---|---|
| CAR | Committed packets | Best effort service |
| | (congestion-free service) | and/or dropped |
| IRL or ORL | Best effort service | Dropped |

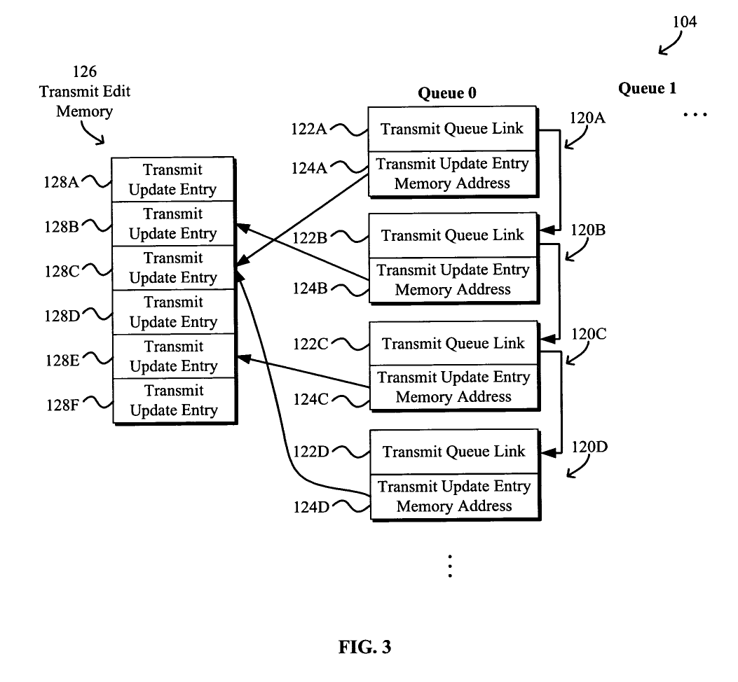

The network device performs the resource reservation function by managing the packet buffer memory 106, and transmit queue entries (TxE) and transmit queue (TxQ) links of the transmit queue 104. FIG. 3 is a block diagram illustrating the general structure of the transmit queue 104 as implemented in hardware. The transmit queue 104 is a link list structure having multiple transmit queue entries 120. It is noted that although only one transmit queue 104 is shown, there are typically multiple transmit queues per transmit port. For example, in one implementation, each transmit port has eight (8) transmit queues per transmit port. In addition, it is further noted that although four transmit queue entries 120 are shown for the transmit queue 104, any suitable number of linked transmit queue entries may be provided.

Each transmit queue entry 120 contains a transmit queue link 122 and a transmit update entry memory address 124. Within a given transmit queue 104, the transmit queue link 122 of each transmit queue entry 120 points to the next transmit queue entry, as indicated by arrows from transmit queue link 122A to transmit queue entry 120B, from transmit queue link 122B to transmit queue entry 120C, and from transmit queue link 122C to transmit queue entry 120D. A transmit queue entry 120 is consumed when the corresponding packet is either sent or dropped (e.g., pushed out such as by being head-dropped).

The transmit update entry memory address 124 of each transmit queue entry 120 points to a location in the transmit queue edit memory 126 that contains information for packet header updates as well as the address of the packet in packet memory. Each transmit update entry memory address 124 points to a transmit update entry 128 in the transmit queue edit memory 126. Any of the transmit update entries 128 may be pointed to by multiple transmit queue entries 120 such as may be the case with a multicast packet. For example, in FIG. 3, transmit update entry 128C is pointed to by two transmit update entry memory addresses 124A, 124D of transmit queue entries 120A, 120D, respectively.

As is evident, implementation of CAR seeks to guarantee a minimum packet memory space for CAR packets. This guarantee of memory space for CAR packets may be achieved by utilizing static packet buffer memory reservation in which a separate packet buffer memory space is reserved for each CAR flow. Static reservation is a way to partition the packet buffer memory space between CAR and non-CAR traffic. Thus, non-CAR traffic will not be allowed to utilize the packet buffer memory space reserved for CAR even when there is available memory space in the space reserved for CAR traffic.

To utilize the available memory space for increased efficiency while guaranteeing memory space for CAR packets, the guarantee of memory space for CAR packets is preferably achieved using dynamic rather than static memory reservation of the packet buffer memory space between CAR and non-CAR traffic flows. The dynamic memory reservation of the packet buffer memory space is made depending on the traffic rate profile and the current usage of the memories. Dynamic memory reservation preferably employs a push-out mechanism (e.g., head-drop) for non-CAR packets. Thus when memory is not congested, all memory space is eligible for non-CAR packets to utilize. However, during times of network congestion, a push-out head-drop mechanism frees memory space for CAR packets. Because non-CAR packets can be pushed out upon detection of network congestion, the memory space occupied by non-CAR packets are effectively seen as free memory space for CAR packets. In contrast with static memory reservation, dynamic memory reservation eliminates the need for hard boundaries to restrict non-CAR packets.

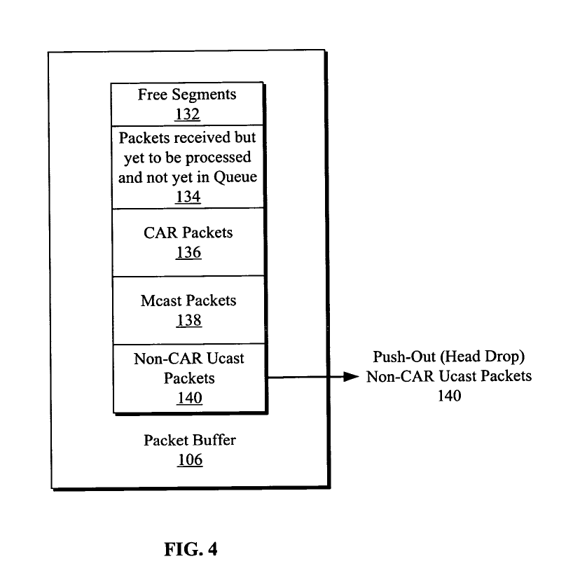

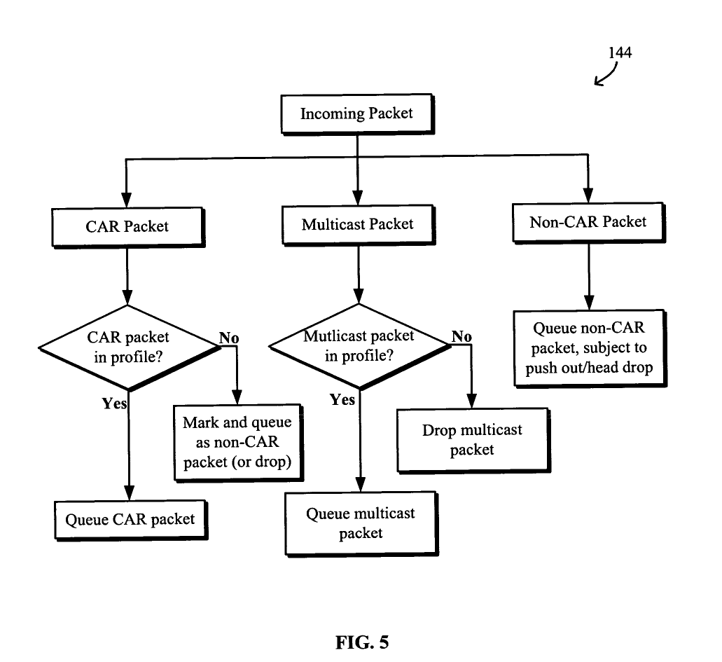

Dynamic memory reservation of packet buffer memory space will be described in more detail with reference to FIG. 4. In particular, FIG. 4 is a block diagram illustrating the packet buffer memory 106. As shown, the packet buffer memory 106 includes a free segments portion 132, a portion for packets that have arrived at the network device but have not yet been processed by the control pipe and hence are not yet in the queue 134, a CAR packets portion 136, a multicast (Mcast) packets portion 138, and a non-CAR unicast (Ucast) packets portion 140. It is to be understood that a memory portion merely refers to an budgeted or allocated amount of space and not to any particular memory address range. Memory allocations and management for CAR packets, non-CAR Mcast packets and non-CAR Ucast packets are summarized in TABLE 2 and in a flow diagram 144 in FIG. 5 and described in more detail below.

TABLE 2

| | | Tracking/ |
|---|---|---|
| Buffer Space | Buffer Space Allocation | Counter |
| CAR Packets | Static (Token bucket restricts amount of | CAR Counter, |
| | packet memory used; out of profile CAR | token bucket |
| | packets reclassified as non-CAR Ucast | model |
| | packets) | |
| Mcast | Static (Memory allocation limited to | Mcast Counter |
| Packets | configured threshold) | |
| Non-CAR | Dynamic (No separate threshold to restrict | Optional |
| Ucast | Packet memory usage) | non-CAR |
| Packets | | Counter |

The multicast (Mcast) packets portion 138 preferably has a statically configured amount of space so as to ensure the quality of Mcast traffic such as streaming and/or interactive audio/video traffic. Because the packet buffer memory 106 utilized by each Mcast packet can only be made available when all corresponding Mcast transmit queue entries 120 have been either transmitted or dropped, pushing out Mcast links in the transmit queue 104 does not necessarily free the space in the packet buffer memory 106. Thus, best effort multicast (Mcast) packets are preferably separated from best-effort unicast (Ucast) packets, i.e., packets coming from and going to a single network. In addition to separating the multicast traffic, the memory space allocated for multicast packets is preferably limited to a predefined maximum or threshold packet memory space. As shown in FIG. 5, if the incoming packet is a multicast packet and in profile, then the multicast packet is queued. Otherwise, the out of profile multicast packet is dropped.

Such separation of multicast traffic allows dynamic packet buffer memory allocation as will be described in more detail below to improve the efficiency of packet memory utilization without limiting the quality of multicast traffic. The multicast packet threshold facilitates in tracking segments used by multicast packets. When the multicast threshold is exceeded, the network device preferably tail drops incoming requests to the multicast queue.

Packet buffer memory space is dynamically allocated for the non-CAR unicast packets portion 140. In particular, the network device dynamically allocates (loans) memory reserved for CAR packets and/or multicast packets to non-CAR unicast packets when these two memories are not being fully utilized by CAR packets and/or by multicast packets, respectively. In other words, when the CAR-packet network traffic is not congested, i.e., when memory reserved for CAR packets is not being fully utilized by CAR packets, the network device may dynamically allocate (loan) memory reserved for CAR packets to non-CAR unicast packets. Similarly, when the multicast network traffic is not congested, i.e., when memory reserved for multicast packets is not being fully utilized by multicast packets, the network device may dynamically allocate (loan) memory reserved for multicast packets to non-CAR unicast packets. Such dynamic memory allocation allows non-CAR packets to utilize memory spaced otherwise reserved for CAR packets and/or multicast packets when space is available in either or both of these portions of the packet buffer memory 106. As shown in FIG. 5, queued non-CAR packets are subject to be pushed out (e.g., head dropped).

On the other hand, when the network device packet memory space becomes congested, a push out mechanism is preferably implemented to push out non-CAR unicast packets from the network device to free up space for incoming CAR packets and/or multicast packets. For example, a head drop mechanism may be implemented. The push out mechanism thus returns memory space previously dynamically allocated (loaned) to non-CAR packets back to CAR or multicast packets. Note that non-CAR unicast packets are preferably sent to separate transmit queues so that they are more accessible for head drop when necessary. As is evident, because a non-CAR unicast packets can be pushed out of the memory space reserved for CAR and/or multicast packets upon detection of network congestion, the memory space occupied by the non-CAR packets in the CAR memory space are effectively free memory space for CAR and multicast packets. Therefore, hard boundaries to restrict non-CAR packets are unnecessary and may be eliminated to thereby improve efficiency.

Referring again to FIG. 2, the control pipe 102 includes the CAR token bucket 112 for checking and measuring the traffic rate profile of the incoming CAR packet against the SLA. The token bucket ensures that the minimum QoS guarantee for the particular traffic flow is met by ensuring that incoming CAR packets do not violate the configured traffic rate profile as defined by the SLA. If an incoming CAR packet violates the configured traffic rate profile as defined by the SLA, then the CAR packet is marked as out of profile CAR packet and may be reclassified as a non-CAR unicast packet to be dropped or transmitted using best efforts. As shown in FIG. 5, out of profile CAR packets are marked and queued as non-CAR packets subject to be pushed out, e.g., head dropped, or may altogether be dropped. In one embodiment, the control pipe 102 is configured with 512 general purpose token buckets. Each token bucket can be configured for a particular mode of the traffic flow (e.g., CAR, IRL, ORL). The control pipe 102 may be configured with a set of rules where if a given packet matches one of the rules, the packet is classified to the appropriate bucket according to the rule to which it matches.

The control pipe 102 also includes the optional non-CAR counter 114 which may be employed to measure non-CAR packet memory usage. However, the non-CAR counter 114 is not necessary for packet memory management. The control pipe 102 further includes the multicast counter 116 to ensure that the threshold for multicast packets is not exceeded. Although not shown, a free space counter may be employed to track the number of free segments in memory. A predetermined number of memory segments should be kept free to allow for a finite reaction time for the network device (time that it takes a packet to be processed in the control pipe). The free segments portion of memory 132 is shown in FIG. 4. As an example, the free segments portion 132 may be approximately 20 segments or approximately 1.2 kB which is relative small portion of a 1 to 2 MB memory.

The push-out based dynamic memory allocation mechanism facilitates in supporting more CAR QoS agreements while dedicating less packet buffer memory to meet those QoS agreements. In other words the allocation mechanism provides the ability to support CAR QoS agreements with a low-cost silicon network device or switch by using a relatively small amount of embedded packet buffer (cache) memory. In one embodiment, the embedded packet buffer (cache) memory can be approximately 1-2 MB in size but any other suitable memory size may be employed. The memory allocation mechanism also allows for the ability to share CAR and non-CAR memory resources while at the same time guaranteeing availability of resources for CAR packets whenever it is needed.

In addition to the non-CAR unicast packet push out mechanism, the control pipe preferably also detects network congestion to begin head-dropping and tail-dropping packets. To detect network congestion, the free memory space in the packet memory is monitored. If the free memory space crosses a predetermined threshold, the push out process will begin. The threshold only needs to match the push out speed in the PMM. For example, if the PMM takes 30 clocks to start wire-speed (full speed) dropping, the threshold only needs to trigger before the free memory space falls below a level requires to store packets that may arrive over a 30 clock period. This makes most of the memory available for storing the packets rather than reserving an unnecessarily large amount of memory space as a buffer zone in order for the packet dropping mechanism to function properly.

Preferably, the control pipe detects network congestion by implementing two buffer congestion thresholds MAX and HIGH. The control pipe head and tail drops non-CAR unicast packets when the HIGH buffer congestion threshold is crossed. When the MAX threshold is also crossed, the control pipe preferably implements a more aggressive packet selection for dropping than is the case when the HIGH threshold is crossed.

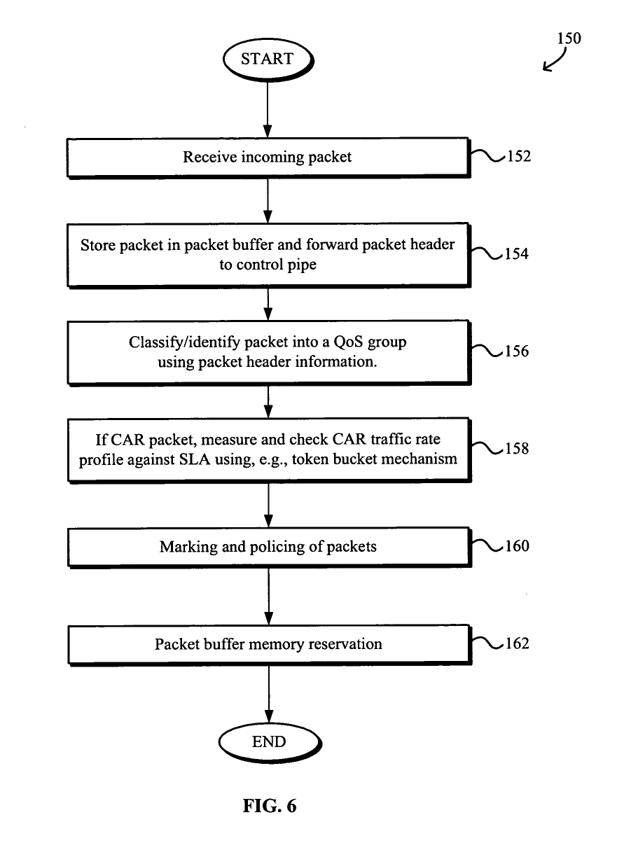

FIG. 6 is a flowchart illustrating a process 150 performed by the network switch implementing CAR architecture. At 152, the network device receives an incoming packet. At 154, the packet is stored in the packet buffer and the packet header is forwarded to the control pipe of the network device. At 156, the control pipe classifies and identifies the packet into a QoS group using the packet header information. At 158, the control pipe measure and checks the traffic rate profile against the SLA using, e.g., the token bucket mechanism. At 160, the control pipe marks and polices packets depending on whether the packet is in profile or out of profile. At 162, the control pipe performs packet buffer memory reservation function. Although process 150 is shown in a given order, it is to be understood that the functions need not be performed in the order given and may be performed simultaneously with any number of suitable other functions.

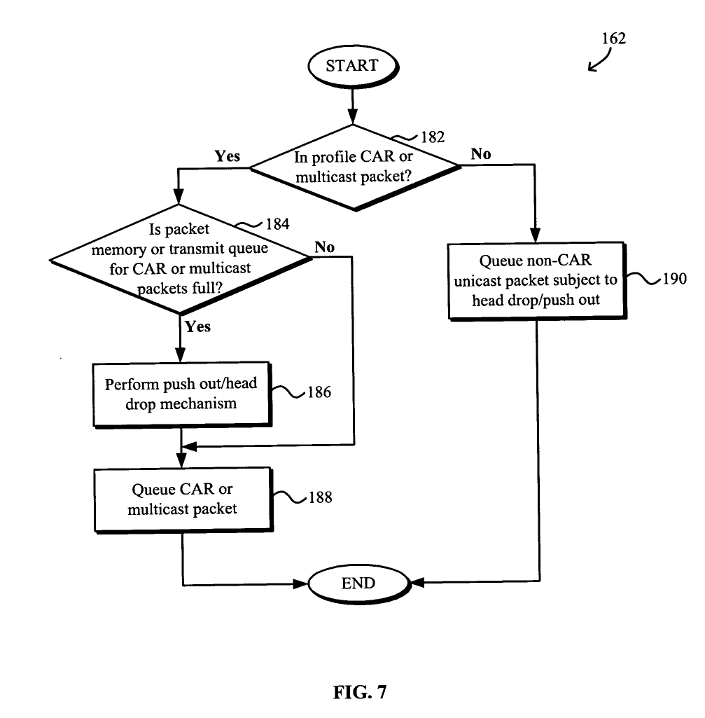

FIG. 7 is a flowchart illustrating packet buffer memory reservation process 162 in more detail. In particular, process 162 determines whether the packet is either an in-profile CAR packet or an in-profile multicast packet 182. If the packet is an in-profile CAR or multicast packet, then process 162 determines at 184 whether the packet memory or transmit queue corresponding to CAR or multicast packets is full. If full, then push out mechanism (e.g., head drop) is performed at 186 and then the process proceeds to 188. Alternatively, if the packet memory and transmit queue corresponding to CAR or multicast packets are not full, then process 162 proceeds directly to 188 in which the in-profile CAR or multicast packet is queued.

If the incoming packet is determined not to be an in-profile CAR packet or an in-profile multicast packet at 182, then the packet is a non-CAR packet. In which case, the non-CAR packet is queued at 190 and is subject to be pushed out (e.g., head dropped).

As is evident, the CAR architecture facilitates in guaranteeing minimum packet memory space and transmit queue entries for CAR packets, sharing memory across as many traffic classes as possible such as by providing dynamic rather than fixed boundary between CAR and non-CAR memory spaces, providing separate queue and threshold for multicast packets, and providing the capability to provide best effort service for out of profile CAR packets.

With the above-described CAR architecture, the network switch can handle all types of network traffic and address supervision problems encountered with networks where Mcast burst issues are common. The CAR mechanism lowers the costs in supervising a network for congestion yet allows higher quality of service for QoS traffic groups. Such architecture facilitates in providing CAR in a low-cost enterprise network device.

While various embodiments are described and illustrated herein, it will be appreciated that they are merely illustrative and that modifications can be made to these embodiments without departing from the spirit and scope of the invention. Thus, the invention is intended to be defined only in terms of the following claims.

1. A method for providing committed access rate (CAR), comprising:
classifying each received packet in an IP/Ethernet network into one of a plurality of quality of service (QoS) groups using information in a header of the packet;
measuring and checking a traffic rate profile of the received packet against a corresponding service level agreement (SLA), marking the packet as one of an in profile packet and an out of profile packet; and
performing packet buffer memory reservation to guarantee memory space for in profile CAR packets.

2. The method of claim 1, wherein said classifying of the packet is performed by a control pipe via a content addressable memory (CAM).

3. The method of claim 2, wherein said CAM comprises a multi-bank ternary CAM (T-CAM) to provide packet classification.

4. The method of claim 1, wherein said measuring and checking is via a token bucket model token.

5. The method of claim 1, wherein said measuring and checking is realized in hardware.

6. The method of claim 1, wherein a CAR packet is an in profile packet if the CAR packet is within the corresponding SLA so that the CAR packet receives congestion-free service and wherein a CAR packet is marked as an out of profile packet if the CAR packet exceeds the SLA and is one of provided with best effort service and dropped.

7. The method of claim 1, wherein said measuring and checking facilitates in controlling CAR packets, input rate limiting (IRL) packets and output rate limiting (ORL) packets.

8. The method of claim 7, wherein IRL and ORL in profile packets receive best effort service and wherein IRL and ORL out of profile packets are dropped.

9. The method of claim 1, wherein said performing buffer memory reservation is via static memory reservation wherein memory space is statically partitioned between CAR packets and non-CAR packets.

10. The method of claim 1, wherein said performing buffer memory reservation is via dynamic memory reservation, wherein packet buffer memory for non-CAR packets is dynamically allocated, and wherein a push-out mechanism is employed for non-CAR packets.

11. The method of claim 1, wherein a separate multicast queue and a separate multicast threshold are defined for multicast packets, and wherein a multicast counter facilitates in tracking multicast packets.

12. A network device for providing committed access rate (CAR), comprising:
a control pipe configured to classify each received packet in an IP/Ethernet network into one of a plurality of quality of service (QoS) groups using information in a header of the packet, the control pipe being further configured to measure and check a traffic transmission rate profile of the received packet against a corresponding service level agreement (SLA), to mark the packet as one of an in profile packet and an out of profile packet, and to perform packet buffer memory reservation to guarantee memory space for in profile CAR packets;
a transmit queue in communication with the control pipe; and
a packet buffer memory in communication with the transmit queue and configured to receive and store received packets, the control pipe being configured to perform packet buffer memory reservation to guarantee packet buffer memory space for in profile CAR packets.

13. The network device of claim 12, wherein the classification of the packets by the control pipe is performed via a content addressable memory (CAM).

14. The network device of claim 13, wherein the CAM comprises a multi-bank ternary CAM (T-CAM) to provide packet classification.

15. The network device of claim 12, wherein control pipe employs a token bucket model to measure and check the traffic transmission rate profile of the received packet, the token bucket model facilitates in controlling CAR packets, input rate limiting (IRL) packets and output rate limiting (ORL) packets.

16. The network device of claim 15, wherein the token bucket model is realized in hardware.

17. The network device of claim 15, wherein IRL and ORL in profile packets receive best effort service and wherein IRL and ORL out of profile packets are dropped.

18. The network device of claim 12, wherein a CAR packet is an in profile packet if the CAR packet is within the corresponding SLA so that the CAR packet receives congestion-free service and wherein a CAR packet is marked as an out of profile packet if the CAR packet exceeds the SLA and is one of provided with best effort service and dropped.

19. The network device of claim 12, wherein buffer memory reservation is via static memory reservation in which memory space is statically partitioned between CAR packets and non-CAR packets.

20. The network device of claim 12, wherein buffer memory reservation is via dynamic memory reservation in which packet buffer memory is dynamically allocated for non-CAR packets, and wherein a head-drop mechanism is employed for non-CAR packets.

21. The network device of claim 12, wherein a separate multicast queue and a separate multicast threshold are defined for multicast packets, and wherein a multicast counter facilitates in tracking multicast packets.

22. A method for providing committed access rate (CAR) in a communications network, comprising:
classifying each received packet into one of a plurality of quality of service (QoS) groups using information in a header of the packet;
for a multicast packet, measuring and checking a multicast traffic rate profile of the received multicast packet using a corresponding multicast packet counter,
for a CAR packet, measuring and checking a traffic rate profile of the received CAR packet against a corresponding service level agreement (SLA),
marking each CAR and multicast packet as one of an in profile packet and an out of profile packet;
for each in profile packet, pushing out queued non-CAR packet if at least one of corresponding packet buffer memory and transmit queue is full; and
queue CAR packet into transmit queue memory.

23. The method of claim 22, further comprising dropping an out of profile multicast packet.

24. The method of claim 22, further comprising marking and queuing an out of profile CAR packet as a non-CAR packet.
